(19) United States
(12) Patent Application Publication
(10) Pub. No.: US 2002/0163390 A1
(43) Pub. Date: Nov. 7, 2002

(54) Analog/digital carrier recovery loop circuit

(76) Inventor: Donald C. Richardson, Plano, TX (US)

Correspondence Address: TEXAS INSTRUMENTS INCORPORATED, P O BOX 655474, M/S 3999, DALLAS, TX, 75265

(21) Appl. No.: 09/847,778

(22) Filed: May 2, 2001

(51) Int. Cl. H03L 7/093

(52) U.S. Cl. 331/17; 331/1 A; 331/25; 375/376

(57) ABSTRACT

A circuit for carrier signal recovery in a communications system having a phase detector output that switches between digital high and low levels and a voltage-controlled oscillator and circuits for deriving the phase detector output, the voltage-controlled oscillator being implemented as analog circuits and the processing of the phase detector output in order to derive a control signal for the voltage-controlled oscillator being implemented as digital circuits

### TECHNICAL FIELD OF THE INVENTION

This invention relates to phase locked loops and more particularly to an analog/digital carrier signal recovery circuit utilizing a digital filter and a digital to analog converter.

### BACKGROUND OF THE INVENTION

Phase locked loops are used extensively in electronics to provide a signal whose frequency can be easily varied and whose stability can be maintained by a reference oscillator. Traditional analog phase-locked loops contain a phase detector 2, a loop filter 4, and a voltage-controlled oscillator (VCO) 6. A prior art traditional analog phase-locked loop is shown in FIG. 1.

The loop filter in systems, such as that shown in FIG. 2a, which filter the phase error signal in order to generate the control voltage for the VCO, is typically implemented in analog form as either a charge pump (as shown in FIG. 2b) or as a continuous-time filter. Because the loop filter is usually low frequency, it is especially suited to be implemented digitally.

Prior art systems which implement digital filters have generally resulted in systems where the entire loop is digital or entirely digital with the exception that a digital-to-analog converter (DAC) is used to generate a control voltage for an analog VCO. In either case, high-performance analog-to-digital converters (ADCs) are needed either prior to a phase detector to perform phase detection by sampling. While the DAC for the VCO control voltage may be low frequency and easy to implement, the ADC prior to the phase detector is typically high frequency and difficult to implement. Also at high frequencies, the use of an ADC at the beginning of the carrier loop and implementation of digital technology for the rest of the loop is especially difficult to implement. ADCs, in general, tend to be expensive to implement.

In carrier recovery and similar communications applications, there is often additional filtering prior to the phase detector that acts as channel filtering for rejection of adjacent channels or for reduction of inter-symbol interference. An example of such a system is one in which a demodulator is present and the phase error signal is derived from its output. FIG. 3 illustrates such a system known as a Costas carrier recovery loop. FIG. 3 was taken from page 436 of the textbook entitled Principles of Communications Systems by Taub and Schilling published in 1986 by McGraw-Hill.

The recovery loop utilizes quadrature (I and Q) channels and comprises two phase locked loops that employ a common VCO and loop filter. Just as in other prior art carrier systems, the input signal to the VCO will serve to keep the VCO oscillating at the carrier frequency. However, the implementation of explicit ADC's in this recovery loop in order to utilize a digital loop filter will be both complicated and expensive as in other prior art carrier recovery systems.

### SUMMARY OF THE INVENTION

These and other problems are generally solved or circumvented, and technical advantages are generally achieved, by the present invention which is a circuit and method for carrier signal recovery in a communications system. The circuit is cost efficient, is easily implemented in an integrated circuit, is low frequency, and is easily reconfigurable.

In one embodiment of the invention, the circuit comprises a phase detector for comparing the frequency of an input signal to the frequency of a reference signal to result in a digital error signal, an averaging circuit coupled to the phase detector and including an input to receive the digital error signal, a digital-to-analog converter with an input coupled to a digital output of the averaging circuit, and a voltage-controlled oscillator coupled between the phase detector and the digital-to-analog converter. The voltage-controlled oscillator receives the analog signal from the digital-to-analog converter as a control signal and generates the reference signal for the phase comparator.

In another embodiment, the circuit further includes a quadrature amplitude modulation circuit whereby the analog input signal can be represented in the complex plane by two components. The quadrature amplitude modulation circuit produces encoded signals that are then input into the phase detector and compared to a reference signal.

One advantage of a preferred embodiment of the present invention is that it utilizes both analog and digital technology while eliminating the need for an expensive and complicated high performance ADC.

Another advantage of a preferred embodiment of the present invention is that it allows the bandwidth of the digital circuitry to be reconfigured as needed.

A further advantage of a preferred embodiment of the present invention is that the implementation of the low frequency response of the digital circuitry is optimized to allow operation of the DAC at a low sampling rate.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a prior art phase locked loop circuit;

FIGS. 2a and 2b illustrate a prior art carrier recovery circuit and a charge pump;

FIG. 3 illustrates a prior art Costas carrier recovery loop;

FIG. 4 is a preferred embodiment of the present invention; and

FIG. 5 is another preferred embodiment of the present invention implementing quadrature channels (I and Q).

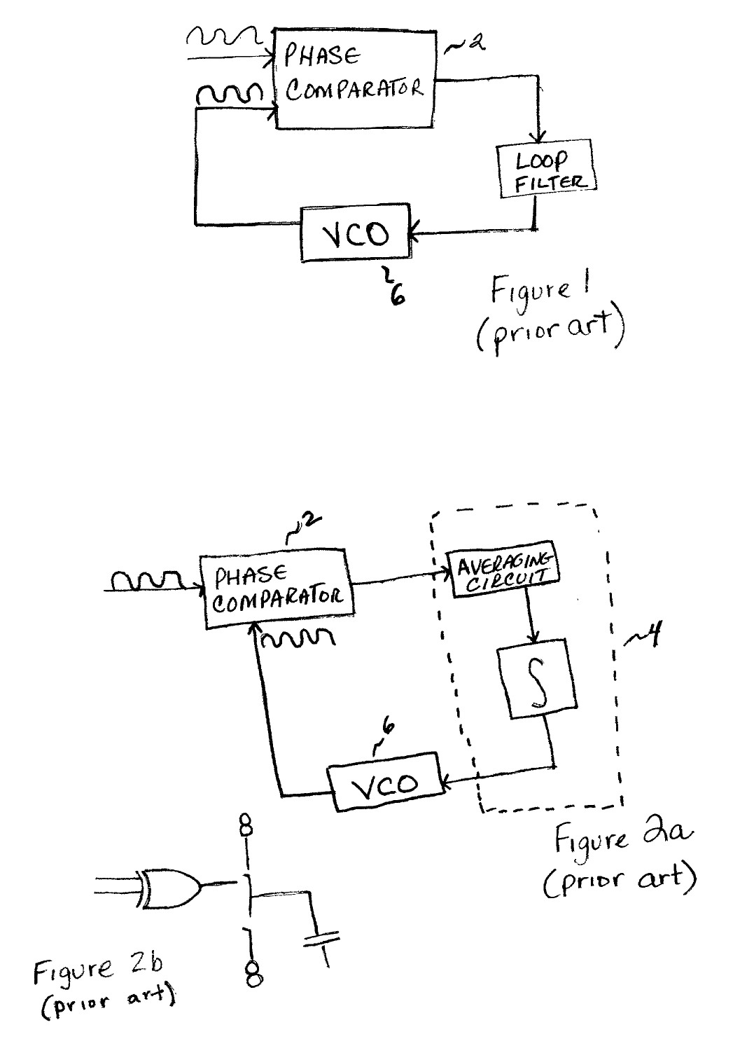

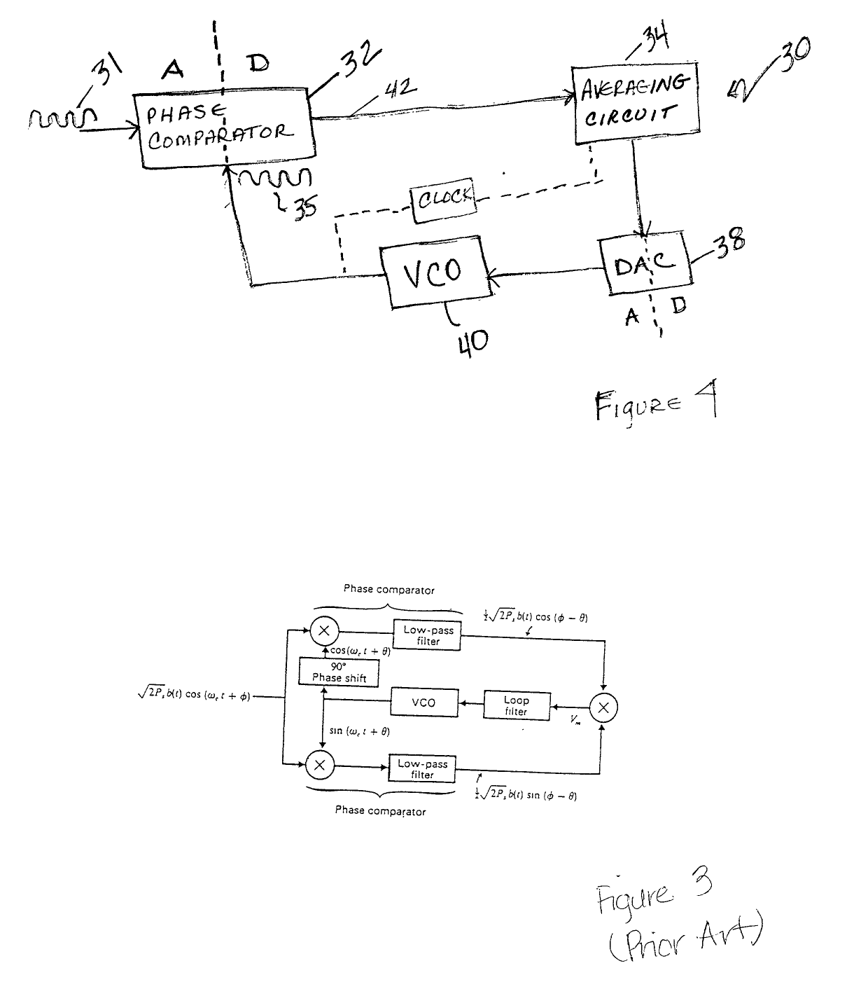

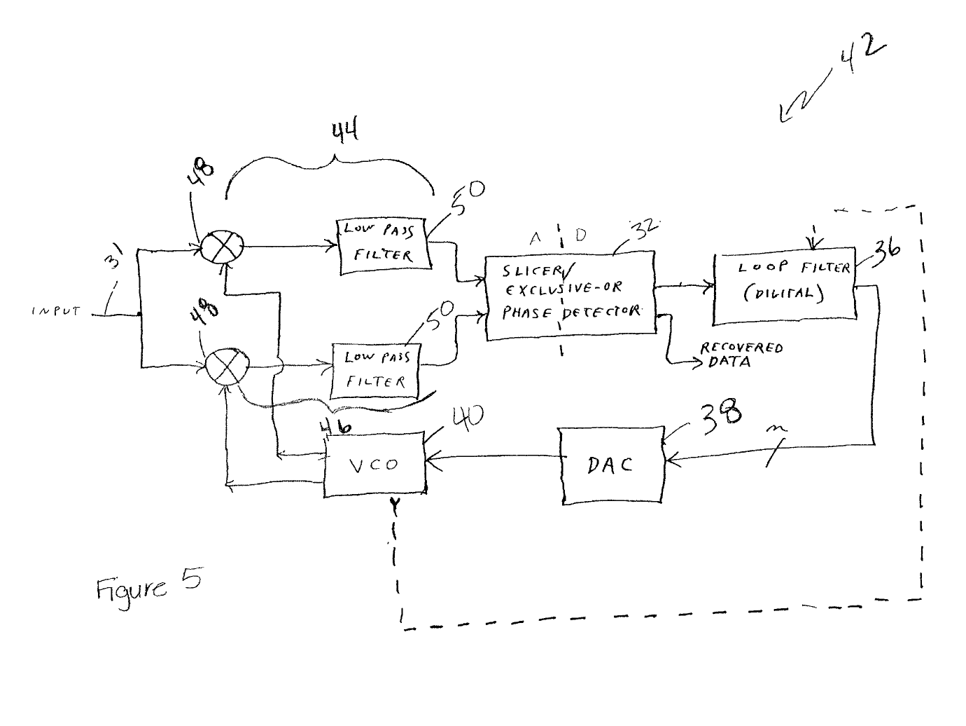

### DETAILED DESCRIPTION OF THE PREFERRED EMBODIMENTS

The making and using of the presently preferred embodiment is discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention facilitates carrier signal recovery utilizing both analog and digital technology. In carrier signal recovery both analog and digital technology can be utilized along the circuit path. The interface between analog and digital portions of the circuit are accomplished utilizing ADCs and DACs. The preferred embodiment of the present invention utilizes digital technology and inventive partitioning which eliminates the need for an expensive and complicated high performance ADC.

In this context, a digital signal is one that has discrete values. The preferred embodiment utilizes binary signals (i.e., digital signals with two discrete values), but other embodiments could have other digital signals. An analog signal, on the other hand, is a signal that can have any value within a voltage (or current) range.

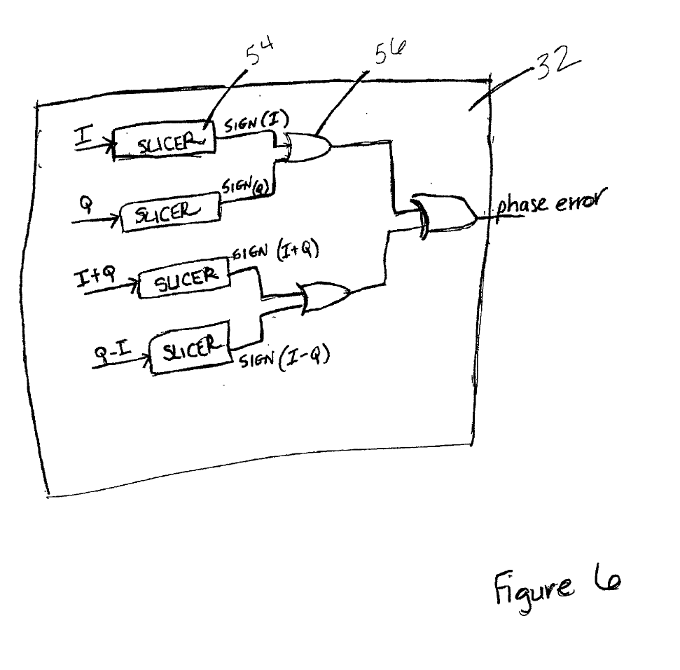

FIG. 4 illustrates a preferred embodiment of the present invention. The circuit 30 comprises a phase detector (or phase comparator) 32 which performs comparator operations, an averaging circuit 34, a DAC 38, and a voltage-controlled oscillator (VCO) 40. The phase detector 32 compares an analog input 31, e.g. a sine wave, to the output of the VCO 40, which can also be a sine wave. The phase detector 32 comprises analog magnitude comparators (e.g. slicers) and logic gates as in the prior art and thus generates a digital error signal 42 that represents the phase difference between the analog input signal 31 and the output of the VCO 40. The digital error signal 42 is an asynchronous signal with digital levels. Thus, a partition between analog and digital circuitry occurs at the phase detector 32. There is no explicit ADC to complicate the overall carrier recovery circuit or increase the costs associated with the circuit.

Once the digital error signal 42 substantially equals zero, the output of the VCO 40, a reference signal 35, is phase locked onto the data that is incoming in the analog signal input 31. Exclusive-OR/slicer technology may be used to perform the comparator operations. For example, the comparator operations can result in square waves representative of the sine wave inputs into the phase detector 32. The signals can then be fed into an Exclusive-OR gate to produce a high or “1” whenever the analog input signal 31 and the reference signal 32 have a different phase or an error signal equal to one. In another embodiment, the comparator operations may be performed with an analog multiplier or with circuitry comprising at least one flip-flop.

The averaging circuit 34 is coupled to the output of the phase detector 32. The averaging circuit 34 can be implemented as a digital low pass filter, possibly followed by a digital integrator, to provide the necessary filtering of the higher frequency components and perform a correlation function. Although described herein as two separate elements, it should be recognized that the averaging circuit 34 and phase detector 32 may be implemented as one element.

Because digital filters are sampled systems, one consideration in this embodiment is the sampling of the digital error signal 42 from the phase detector 32. Undersampling techniques may also be used, otherwise a high sample rate might be needed to capture the frequency content of the digital error signal 42. Furthermore, the output of the digital filter is typically low frequency, thus decimation within the digital filter can be utilized to optimize implementation of its low frequency response and allow operation of the DAC 38 at a low sampling rate. Preferably the clock of the digital filter is derived from the output of the VCO 40, as shown in FIG. 4, to reduce the intermodulation that may occur if the digital loop filter is clocked with an unrelated clock signal.

The DAC 38 is designed to provide a digital to analog partition which does not affect adversely affect the design and implementation of the circuit 30. The particular kind of DAC 38 used can be chosen depending on system parameters. Because the bandwidth requirement of the VCO control voltage is typically low, the DAC 38 may include a smoothing filter and/or a resistor string converter having one or more resistors. Also, in order to decrease the noise of this control voltage, an oversampled sigma-delta converter or some other kind of noise-shaping converter could be used if care is taken to minimize or reduce the effects of any undesirable tones.

FIG. 5 illustrates another preferred embodiment of the present invention in which quadrature amplitude modulation is utilized. In this embodiment, quadrature modulation channels, I and Q, 44 and 46, respectively, are implemented in the circuit 42. While the performance of the phase detector 32, digital filter 36, DAC 38, and VCO 40 are generally the same as discussed in the previous embodiment, this embodiment is a robust design which provides additional filtering of the input signal prior to the phase detector. This additional filtering acts as channel filtering for rejection of adjacent channels or for reduction of inter-symbol interference.

This embodiment allows the input signal 31 to be represented in the complex plane (I,Q). The analog input signal, then, comprises two signal components. Also because each signal can be represented in the complex plane, multiple signals may be transmitted simultaneously.

Each of the channels 44, 46 receive one of the two signal components. Each channel comprises a multiplier 48 coupled to a low pass filter 50 which is in turn coupled to the phase detector 32. The low pass filters 50 suppress the high-frequency terms of the signal components. The two signal components are received by the phase detector 32. At this point the circuit operates in substantially the same manner as described in the previous embodiment. The phase detector 32 may use slicers 54 and exclusive-OR gates 56 to generate a digital phase error output equal to (sign(I) XOR sign(Q)) XOR (sign(I+Q) XOR sign(Q-1)) as shown in FIG. 6. In this embodiment, the sampling of the phase error signal may be performed by the slicers 54 themselves or can be done within the phase detector 32 after the slicers 54.

The VCO 40 is designed to output a reference signal that can also be represented in the complex plane with two reference signal components. These reference signal components are input into the channels 44,46. When the VCO 40 is in synchronism with the input signal 31, the output of the I channel 44 and the output of the Q channel 46 are the desired demodulated signals. Digital versions of these signals from the outputs of slicers 54 in the phase comparator may be preferred.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A circuit comprising:
a phase detector for comparing the frequency of an input signal to the frequency of a reference signal whereby the phase detector generates a digital error signal;
an digital averaging circuit coupled to the phase detector and including an input to receive the digital error signal;
a digital-to-analog converter with an input coupled to a digital output of the averaging circuit, the digital-to-analog converter generating an analog signal relating to the digital signal output of the averaging circuit; and
a voltage-controlled oscillator coupled between the phase detector and the digital-to-analog converter, the voltage-controlled oscillator receiving the analog signal as a control signal and generating the reference signal.

2. The circuit of claim 1 wherein the difference between the frequency of the input signal and reference signal is reduced to result in a locked loop.

3. The circuit of claim 1 wherein the circuit is a carrier recovery circuit for receiving an analog signal from a transmitter.

4. The circuit of claim 1 wherein the phase detector comprises an analog multiplier.

5. The circuit of claim 1 wherein the averaging circuit comprises a low-pass digital filter.

6. The circuit of claim 5 wherein the phase detector has a sampling frequency which is reduced in subsequent stages of the digital filter.

7. The circuit of claim 5 in which the digital filter is clocked with a signal derived from the output of the voltage-controlled oscillator.

8. The circuit of claim 1 in which the digital-to-analog converter comprises a resistor string converter having one or more resistors.

9. The circuit of claim 1 in which the digital-to-analog converter comprises a noise-shaping converter.

10. The circuit of claim 1 further comprising in-phase and quadrature channels, each channel coupled to an input of the phase detector and each channel receiving the input signal.

11. The circuit of claim 10 wherein the in-phase and quadrature channels each include a low-pass filter.

12. The circuit of claim 11 wherein the in-phase and quadrature channels each further include a multiplier, each multiplier coupled to an input of the low-pass filter.

13. The circuit of claim 1 wherein the phase detector is implemented as analog comparators.

14. The circuit of claim 1 wherein the phase detector includes at least one exclusive-OR gate.

15. The circuit of claim 1 wherein the phase detector includes at least one flip flop.

16. The circuit of claim 1 wherein the digital-to-analog converter includes a smoothing filter.

17. A circuit comprising:
a quadrature amplitude modulation circuit whereby an input signal is represented in the complex plane, the quadrature amplitude modulation circuit producing encoded signals;
a phase detector for receiving the encoded signals and comparing the phase of the encoded signals to the phase of a reference signal whereby the phase detector generates a digital error signal;
a digital loop filter coupled to the phase detector and including an input to receive the digital error signal;
a digital-to-analog converter with an input coupled to a digital output of the digital loop filter, the digital-to-analog converter generating an analog signal relating to the digital signal output of the digital loop filter; and
a voltage-controlled oscillator coupled between the phase detector and the digital-to-analog converter, the voltage-controlled oscillator receiving the analog signal as a control signal and generating the reference signal.

18. The circuit of claim 17 wherein the quadrature amplitude modulation circuit comprises an in-phase channel and a quadrature channel.

19. The circuit of claim 18 wherein the in-phase and quadrature channels each comprise a multiplier and a low pass filter.

20. A method of processing a signal, the method comprising:
receiving an analog input signal and an analog reference signal;
generating a digital error signal representing the difference in the frequencies or phases of the analog input signal and the analog reference signal;
converting the digital error signal into an analog error signal; and
varying the frequency or phase of the analog reference signal based upon the analog error signal.

21. The method of claim 20 whereby the analog error signal will cause the frequency of the voltage-controlled oscillator to be varied in a manner that reduces the difference between the phase of the analog input signal and the phase of the reference signal to result in a locked loop.

22. The method of claim 20 wherein converting the digital error signal into an analog signal is performed by a digital-to-analog converter.

23. The method of claim 20 wherein generating a digital error signal comprises filtering a digital output of a phase comparator, the phase comparator output being based upon the analog input signal and the analog reference signal.

24. The method of claim 20 wherein generating a digital error signal comprises performing a correlation calculation to determine an average.

25. A method of processing a signal, the method comprising:
receiving an analog signal and a reference signal to which the analog signal is compared;
modulating the analog signal into an in-phase component and a quadrature component;
generating a digital error signal representing the difference in the frequencies or phases of the analog signal and the reference signal components;
converting the digital error signal into an analog error signal; and
varying the frequency or phase of the reference signal based upon the analog error signal.

26. The method of claim 25 wherein the modulation of the analog signal is performed by a modulation circuit, the modulation circuit comprising an in-phase and a quadrature channel.

27. The method of claim 26 wherein the in-phase and quadrature channel each have a multiplier and a low pass filter.

28. The method of claim 27 wherein converting the digital error signal into an analog signal is performed by a digital-to-analog converter.

29. The method of claim 25 and further comprising generating a filtered digital error signal by digitally filtering the digital error signal, wherein the analog error signal is generated by converting the filtered digital error signal into the analog error signal.

30. The method of claim 25 wherein generating a digital error signal comprises performing a correlation calculation to determine an average.

31. A circuit comprising:
means for generating a digital error signal representing the difference in the frequencies or phases of an input signal and a reference signal;
means for averaging the digital error signal;
means for converting the digital error signal into an analog error signal; and
means for varying the frequency and/or phase of the analog reference signal based upon the analog error signal until the analog reference signal and the input signal have a desired phase difference.

32. The circuit of claim 31 wherein the desired phase difference is substantially zero.
